(19) United States
(12) Patent Application Publication
(10) Pub. No.: US 2008/0178921 A1
(43) Pub. Date: Jul. 31, 2008

(54) THERMOELECTRIC NANOWIRE COMPOSITES

(76) Inventor: Qi Laura Ye, Fremont, CA (US)

Correspondence Address: John P. Wooldridge, Esq., 114 Honu'ea Pl, Kihei, HI, 96753, US

(21) Appl. No.: 11/843,609

(22) Filed: Aug. 22, 2007

Related U.S. Application Data
(60) Provisional application No. 60/839,990, filed on Aug. 23, 2006.

(51) Int. Cl. H01L 35/02; H01L 35/34; H01L 21/441

(52) U.S. Cl. 136/225; 438/54; 438/681; 257/E21.477

(57) ABSTRACT

An MOCVD process provides aligned p- and n- type nanowire arrays which are then filled with p- and n-type thermoelectric films to form the respective p-leg and n-leg of a thermoelectric device. The thermoelectric nanowire synthesis process is integrated with a photolithographic microfabrication process. The locations of the p- and n-type nanowire micro arrays are defined by photolithography. Metal contact pads at the bottom and top of these nanowire arrays which link the p- and n-type nanowires in series are defined and aligned by photolithography.

This application claims priority to U.S. Provisional Patent Application Ser. No. 60/839,990, titled; “Thermoelectric Nanowire Composites”, filed Aug. 23, 2006, incorporated herein by reference.

The invention described herein was made by a nongovernment employee, whose contributions were done in the performance of work under a NASA contract(s), and is subject to the provisions of Public Law 96-517 (35 U.S.C. 202). This invention was made with Government support under one or more of the following NASA awarded, contracts; NAS2-99092, NNA04BC25C, NNAA05BE36C, and NAS2-03144. The Government has certain rights in this invention.

### BACKGROUND OF THE INVENTION

1. Field of the Invention

The present invention relates to thermoelectric nanowire composite devices and methods of manufacturing such devices, and more particularly, it relates to nanowire thermoelectric composite devices with high-energy conversion efficiency and high packing density and the methods of manufacturing such devices.

2. Description of Related Art

The Seebeck effect is the conversion of temperature differences directly into electricity. This effect was first discovered, accidentally, by the German-Estonian physicist Thomas Johann Seebeck in 1821, who found that a voltage existed between two ends of a metal bar when a temperature difference ΔT existed in the bar. The Peltier effect is the reverse of the Seebeck effect; a creation of a heat difference from an electric voltage. It occurs when a current is passed through two dissimilar metals or semiconductors (n-type and p-type) that are connected to each other at two junctions (Peltier junctions). The current drives a transfer of heat from one junction to the other: one junction cools off while the other heats up; as a result, the effect is often used for thermoelectric cooling. This effect was observed in 1834 by Jean Peltier, 13 years after Seebeck's initial discovery.

Typical thermoelectric devices are structured as alternating p-type and n-type semiconductor elements connected by metallic interconnects. Current flows through the n-type element crosses a metallic interconnect and passes into the p-type element. If a power source is provided, the thermoelectric device may act as a cooler. Electrons in the n-type element will move opposite the direction of current flow and holes in the p-type element will move in the direction of current flow, both removing heat from one side of the device. If a heat source is provided, the thermoelectric device may function as a power generator. The heat source will drive electrons in the n-type element toward the cooler region, thus creating a current through the circuit. Holes in the p-type element will then flow in the direction of the current. The current can then be used to power a load, thus converting the thermal energy into electrical energy.

Typical nanowires exhibit aspect ratios (length-to-width ratio) of 1000 or more. As such they are often referred to as 1-Dimensional materials. Nanowires have many interesting properties that are not seen in bulk or 3-D materials. This is because electrons in nanowires are quantum confined laterally and thus occupy energy levels that are different from the traditional continuum of energy levels or bands found in bulk materials. Peculiar features of this quantum confinement exhibited by certain nanowires such as carbon nanotubes manifest themselves in discrete values of the electrical conductance. Such discrete values arise from a quantum mechanical restraint on the number of electrons that can travel through the wire at the nanometer scale. These discrete values are often referred to as the quantum of conductance.

Examples of nanowires include inorganic molecular nanowires (Mo₆S₉ₓIₓ, Li₂Mo₆Se₆), which have a diameter of 0.9 nm, and can be hundreds of micrometers long. Other important examples are based on semiconductors such as InP, Si, GaN, etc., dielectrics (e.g. SiO₂, TiO₂), or metals (e.g. Ni, Pt).

There are many applications where nanowires may become important in electronic, opto-electronic and nanoelectromechanical devices, as additives in advanced composites, for metallic interconnects in nanoscale quantum devices, as field-emitters and as leads for biomolecular nanosensors.

Nanowires are not observed spontaneously in nature and must be produced in a laboratory. Nanowires can be either suspended, deposited or synthesized from the elements. A common technique for creating a nanowire is the Vapor-Liquid-Solid (VLS) synthesis method. This technique uses as source material either laser ablated particles or a feed gas (such as silane). The source is then exposed to a catalyst. For nanowires, the best catalysts are liquid metal (such as gold) nanoclusters, which can either be purchased in colloidal form and deposited on a substrate or self-assembled from a thin film by dewetting. This process can often produce crystalline nanowires in the case of semiconductor materials.

The conductivity of a nanowire is expected to be much less than that of the corresponding bulk material. This is due to a variety of reasons. First, there is scattering from the wire boundaries, when the wire width is below the free electron mean free path of the bulk material. In copper, for example, the mean free path is 40 nm. Nanowires less than 40 nm wide will shorten the mean free path to the wire width.

Some early experiments have shown how nanowires can be used to build the next generation of computing devices. To create active electronic elements, the first key step was to chemically dope a semiconductor nanowire. This has already been clone to individual nanowires to create p-type and n-type semiconductors. The next step was to find a way to create a p-n junction, one of the simplest electronic devices. This was achieved in two ways. The first way was to physically cross a p-type wire over an n-type wire. The second method involved chemically doping a single wire with different dopants along the length. This method created a p-n junction with only one wire. After p-n junctions were built with nanowires, the next logical step was to build logic gates. By connecting several p-n junctions together, researchers have been able to create the basis of all logic circuits: the AND, OR, and NOT gates have all been built from semiconductor nanowire crossings.

Metalorganic chemical vapor deposition (MOCVD) is a chemical vapor deposition process that uses metalorganic source gases. For instance, MOCVD may use tantalum ethoxide (Ta(OC₂H₃)₃), to create tantalum pentoxide (Ta₂O₅), or tetradimethylamino titanium (TDMAT) to create titanium nitride (TiN).

### SUMMARY OF THE INVENTION

It is an object of the present invention to embed N- and P-doped nanowires in a N- or P-type film.

It is another object to embed N- and P-doped nanowires in a N- or P-type TE film.

Another object of the invention is a lithographic method of locating P- and N-type nanowires grown by MOCVD.

Still another object of the invention is to locate P- and N-type nanowires grown by MOCVD and embedded in a N- or P-type TE film.

These and other objects will be apparent based on the disclosure herein.

Embodiments of the invention include MOCVD fabricated, vertically aligned, dense packed arrays of P-type nanowires in one zone and N-type nanowires in another zone, where each zone is embedded in a thermoelectric film. Exemplary embodiments provide methods for synthesizing InSb nanowires and composites thereof. Applications of these composites for energy efficient refrigeration and power generation applications are disclosed. Certain MOCVD device modifications are discussed, including a 3-plenum showerhead, quick flash evaporators and custom designed jet configurations.

In an exemplary process for fabricating thermoelectric nanowire composite arrays by MOCVD, a thin silicon nitride layer is deposited on GaSb substrate by a plasma enhanced chemical vapor deposition method. Photolithography is used pattern the bottom contact pads on the nitride layer on GaSb. Metal e-beam evaporation is used to deposit Au in those pads. TEOS deposition process is conducted on the Au patterned substrate and coat a uniform silicon dioxide layer on top. Photoresist is coated on top of the silicon dioxide layer. Photolithography is used to pattern the p-mask on the resist. Deep reactive ion etching (DRIE) is used to etch the p-holes in the silicon dioxide layer. After etching, the photoresist is stripped by acetone. P-type thermoelectric nanowires are then grown in these holes using MOCVD method. P-type thermoelectric films are then filled up in these holes to embed the p-type nanowires using MOCVD method. P-type composite leg is formed. Chemical mechanical polishing (CMP) method is used to polish away the p-type thermoelectric films that are not in the defined p-holes but on top of the silicon dioxide layer. Photoresist is coated on top of the p-leg filled silicon dioxide layer. Photolithography is used to pattern the corresponding n-mask on the resist. DRIE is used to etch the n-holes in the silicon dioxide layer. After etching, the photoresist is stripped by acetone. N-type thermoelectric nanowires are then grown in these holes using MOCVD method. N-type thermoelectric films are then filled up in these holes to embed the n-type nanowires using MOCVD method. N-type composite leg is formed. CMP method is used to polish away the n-type thermoelectric films that are not in the defined n-holes but on top of the silicon dioxide layer. Photoresist is coated on top of the p-leg and n-leg filled silicon dioxide layer. Photolithography is used to align and pattern the corresponding top metal contact pads on the resist. Metal e-beam evaporation is used to deposit Au in those top contact pads. Photoresist is stripped by acetone. Thermoelectric nanowire composite device can then be fabricated.

The thermoelectric nanowire composites of the present invention can be made into any standard size to fit into conventional thermoelectric modules (coolers and heaters) for their applications. Exemplary thermoelectric nano cooler embodiments are discussed below, particularly with respect to satellite applications.

Most devices including satellite low noise amplifiers, pump laser diodes, and computers generate excess heat and require cooling. The thermoelectric nano coolers enabled by the present invention represent an innovative approach in cooling with much improved efficiency by using nano-engineering materials. Compared with conventional vapor-compression refrigerators or gas-based engines, such solid-state devices are much lighter in weight, much smaller in size, have no moving parts, are environmentally benign, and are much more efficient in cooling. At NASA Ames Center for Nanotechnology, this type of thermoelectric nano cooler has been targeted for satellite low noise amplifier applications. Many more civil, military, and space applications will significantly benefit from these nano coolers. For examples, they can be used to cool electronics, optoelectronics, computer chips, instruments and probing systems. They can also be used as energy recycling units for recovery of waste heat from instruments, automobiles, aircrafts, and space shuttles. They can be heat exchangers, compact chillers, and temperature controllers on space stations, exploration vehicles and habitats.

All thermoelectric coolers are based on the Peltier effect, where an electric current flowing across thermocouple junctions produces cooling. A key measure of the efficiency of this cooling system is called the coefficient of performance (COP), which is directly related to the materials properties that are evaluated by a dimensionless figure of merit ZT. The ZT values of the best bulk thermoelectric materials are low and have remained at a value of about 1 for many decades. The low ZT values severely limit the uses of thermoelectric coolers, in order for thermoelectric coolers to be as efficient as a gas- or vapor-based system, for example, a kitchen refrigerator, a ZT value larger than 3 is needed. Recent advances in Nanotechnology create new opportunities to increase ZT drastically by designing new nano-structured materials that exploit the quantum confinement effect. Nanotechnology allows us to maximize the Peltier effect by charge confinement in one-dimensional structures and structures with high surface to volume ratio. These new materials provide the basis for a new generation of solid-state refrigeration with high efficiency and excellent scalability. The present invention addresses the key steps of fabricating nanowire-based thermoelectric coolers with a much improved figure of merit.

Nanowire-based materials produced by the present methods are grown into one-dimensional quantum wire configuration by a lattice matching metal-organic chemical vapor deposition (MOCVD) method from pattered nano catalyst sites. The p-type and n-type thermoelectric nanowire arrays are embedded in p-type and n-type thermoelectric films to form composites. To build the nanowire composites into workable prototype devices, these p-type and n-type regimes are patterned by a conventional photolithographic method and they are connected electrically in series and thermally in parallel. A fabrication process that integrates traditional semiconductor microfabriation techniques with a controlled nanomaterials synthesis approach has been developed. On a 3-inch GaAs substrate, one present design will produce nine 1 cm by 1 cm nano cooler engines.

The 1 cm by 1 cm cooler engines can be coated with thin film dielectric passivation layers on surfaces (e.g., PECVD silicon nitride) and then deposited with a thin film metal layer (e.g., gold) for wire bonding. An array of such cooler engines can be aligned on satellite low noise amplifier module pads for packaging and testing. This process can be achieved by conventional semiconductor packaging techniques. The packaging materials and processes are selected based on optimizing the interface resistances (both thermal and electrical) and the process temperature limits in order to achieve high reliability and high thermal management efficiency.

The impact of this nano cooler on NASA's future space missions and to the nation's economy will be significant. Thermal management of spacecraft and space station environments is an important issue for both crewed and un-crewed Exploration missions. These new thermoelectric coolers will be much lighter than the current ones. Compared with the current liquid cooling systems, these new coolers are expected to be at least 30% lighter. Because these new nano coolers are much more efficient than the existing ones, significant power reduction is possible. This reducing power consumption can be taken advantage of either to reduce the size and weight of power sources, or to improve the system performance by employing the low noise amplifiers at both RF front-end transmit and receive channels.

Current methods for transporting heat away from spacecraft components and bringing heat to other systems often employ liquid-based heat exchange systems or radiator, pump, motor and motor drive, heat sink or cold plate, fins, heat pipe or conductive tubing, and fluid for liquid cooling. Such systems not only add weight to the spacecraft, affecting maximum payload, but also impact mission lifetime because their complex structures are prone to component malfunction. Thermoelectric nano coolers of the present invention involve no moving parts and can be packed in much more reliable ways than the current cooling systems. With improved efficiency such solid-state devices will be well suited for NASA's future Human and Robotic missions. These innovative new cooling devices are also useful for a wide range of applications in both civil and military platforms.

An embodiment of the invention is a method for fabricating a thermoelectric nanowire composite array. In this Summary of the Invention, the use of the term “may” should be interpreted as “may and can” in this and the following descriptions of embodiments of the invention The steps of this embodiment comprise: depositing an insulating layer on a substrate; forming bottom electrical contacts on the insulating layer; depositing a silicon dioxide layer onto the bottom electrical contacts; producing a p-composite and an n-composite, wherein producing a p-composite comprises: coating a first photoresist layer onto the silicon dioxide layer; patterning first openings in the first photoresist layer to produce a mask selected from a group consisting of a p-mask and an n-mask; etching in the first openings to etch away portions of the silicon dioxide layer to produce first holes that exposes first portions of the bottom electrical contacts; stripping away the first photoresist layer; depositing p-type nanowires in the first holes to produce p-holes; depositing p-type film in the p-holes to embed the p-type nanowires in the p-type film to produce a p-composite in each the p-hole; and polishing away excess p-type film, and wherein producing an n-composite comprises: coating a second photoresist layer on the silicon dioxide layer and over the p-holes; patterning second openings in the second photoresist layer to produce an n-mask; etching in the second openings to etch away portions of the silicon dioxide layer to produce second holes that exposes second portions of the bottom electrical contacts; stripping away the second photoresist layer; depositing n-type nanowires in the second holes to produce n-holes; depositing n-type film in the n-holes to embed the n-type nanowires in the n-type film to produce an n-composite in each the n-hole; and polishing away excess n-type film; and forming top metal contact pads to electrically connecting a p-composite to an n-composite. The insulating layer may be deposited through a TEOS (Tetraethyl orthosilicate) CVD process and may comprise silicon nitride. The first photoresist layer and second photoresist layer may be spin-coated onto the silicon dioxide layer. Each of the p-type nanowires, the p-type film, the n-type nanowires and the n-type film may be deposited by an MOCVD process. The MOCVD process may use a three-plenum showerhead in the MOCVD reaction chamber. The three-plenum showerhead permits separate delivery of three MO materials to the gap between the substrate and the showerhead with no pre-mixing of gases. The three-plenum showerhead may comprise at least 250 jets. The MOCVD process may use metal organic precursors selected from the group consisting of Pentamethylcyclopentadienylindium (CH₃)₅C₅In in octane, Triphenylarsine (C₆H₅)₃As in octane, Tris(2,2,6,6-tetramethyl-3,5-heptanedionato)gallium Ga(TMHD)₃ in octane, Triphenylbismuth (C₆H₅)₃Bi in octane, Triphenylantimony (C₆H₅)₃Sb in octane and Tellurium ethoxide in octane. The p-type nanowires and films may be produced from a combination of metal organic precursors selected from the group consisting of (i) In, Ga and Sb, (ii) In, Bi and Sb and (iii) Bi, Sb and Te. For the p-type nanowires, the In may comprise about 5 wt % Pentamethylcyclopentadienylindium (CH₃)₅C₅In in octane, wherein the Ga may comprise about 5 wt % Tris(2,2,6,6-tetramethyl-3,5-heptanedionato)gallium Ga(TMHD)₃ in octane, wherein the Bi may comprise about 5 wt % Triphenylbismuth (C₆H₅)₃Bi in octane, wherein the Sb may comprise about 5 wt % Triphenylantimony (C₆H₅)₃Sb in octane and wherein the Te may comprise about 5 wt % Tellurium ethoxide in octane. The n-type nanowires and films may be produced from a combination of metal organic precursors selected from the group consisting of (i) In, Sb and Te, (ii) In, As and Sb and (in) Bi, Sb and Te. For the n-type nanowires, the In may comprise about 5 wt. % Pentamethylcyclopentadienylindium (CH₃)₅C₅In in octane, the As may comprise about 5 wt % Triphenylarsine (C₆H₅)₃As in octane, the Ga may comprise about 5 wt % Tris(2,2,6,6-tetramethyl-3,5-heptanedionato)gallium Ga(TMHD)₃ in octane, the Bi may comprise about 5 wt % Triphenylbismuth (C₆H₅)₃Bi in octane, the Sb may comprise about 5 wt % Triphenylantimony (C₆H₅)₃Sb in octane, and the Te may comprise about 5 wt. % Tellurium ethoxide in octane. At least one of (i) the p-type nanowires, (ii) the p-type film, (iii) the n-type nanowires and (iv) the n-type film may be formed from precursors delivered to a MOCVD reaction chamber by quick flash evaporation.

Another embodiment of the invention is a method for fabricating a thermoelectric nanowire composite array, comprising: depositing an insulating layer on a substrate; forming bottom electrical contacts on the insulating layer; depositing a silicon dioxide layer onto the bottom electrical contacts; coating a first photoresist layer onto the silicon dioxide layer; patterning first openings in the first photoresist layer to produce a p-mask; etching in the first openings to etch away portions of the silicon dioxide layer to produce first holes that exposes first portions of the bottom electrical contacts; stripping away the first photoresist layer; depositing p-type nanowires in the first holes to produce p-holes; depositing p-type film in the p-holes to embed the p-type nanowires in the p-type film to produce a p-composite in each the p-hole; polishing away excess p-type film; coating a second photoresist layer on the silicon dioxide layer and over the p-holes; patterning second openings in the second photoresist layer to produce an n-mask; etching in the second openings to etch away portions of the silicon dioxide layer to produce second holes that exposes second portions of the bottom electrical contacts; stripping away the second photoresist layer; depositing n-type nanowires in the second holes to produce n-holes; depositing n-type film in the n-holes to embed the n-type nanowires in the n-type film to produce an n-composite in each the n-hole; polishing away excess n-type film; and forming top metal contact pads to electrically connecting a p-composite to an n-composite.

Another embodiment of the invention is a method for fabricating a thermoelectric nanowire composite array, comprising: depositing an insulating layer on a substrate; forming bottom electrical contacts on the insulating layer; depositing a silicon dioxide layer onto the bottom electrical contacts; coating a first photoresist layer onto the silicon dioxide layer; patterning first openings in the first photoresist layer to produce a n-mask; etching in the first openings to etch away portions of the silicon dioxide layer to produce first holes that exposes first portions of the bottom electrical contacts; stripping away the first photoresist layer; depositing n-type nanowires in the first holes to produce n-holes; depositing n-type film in the n-holes to embed the n-type nanowires in the n-type film to produce an n-composite in each the n-hole; polishing away excess n-type film; coating a second photoresist layer on the silicon dioxide layer and over the n-holes; patterning second openings in the second photoresist layer to produce an p-mask; etching in the second openings to etch away portions of the silicon dioxide layer to produce second holes that exposes second portions of the bottom electrical contacts; stripping away the second photoresist layer; depositing p-type nanowires in the second holes to produce p-holes; depositing p-type film in the p-holes to embed the p-type nanowires in the p-type film to produce a p-composite in each the p-hole; polishing away excess p-type film; and forming top metal contact pads to electrically connecting a p-composite to an n-composite.

Another embodiment of the invention is a method, comprising: MOCVD depositing p-type nanowires onto an electrical contact; and MOCVD deposing p-type thermoelectric film onto the p-type nanowires to embed the p-type nanowires in the p-type thermoelectric film. Another embodiment of the invention is a method, comprising: MOCVD depositing n-type nanowires onto an electrical contact; and MOCVD deposing n-type thermoelectric film onto the n-type nanowires to embed the n-type nanowires in the n-type thermoelectric film. Another embodiment of the invention is a method, comprising: MOCVD depositing p-type nanowires onto an electrical contact; MOCVD deposing p-type thermoelectric film onto the p-type nanowires to embed the p-type nanowires in the p-type thermoelectric film; MOCVD depositing n-type nanowires onto an electrical contact; and MOCVD deposing n-type thermoelectric film onto the n-type nanowires to embed the n-type nanowires in the n-type thermoelectric film. The invention includes at least the apparatuses made by the methods of the invention.

An embodiment of the invention is a thermoelectric nanowire composite, comprising a first plurality of p-type nanowires embedded in a first p-type thermoelectric film, wherein each nanowire of the first plurality of p-type nanowires is aligned to be about parallel with each other nanowire of the first plurality of p-type nanowires.

Another embodiment is a thermoelectric nanowire composite, comprising a first plurality of nanowires embedded within a first thermoelectric film. The first plurality of nanowires may be selected from the group consisting of p-type nanowires and n-type nanowires. The first plurality of nanowires may be about parallel to each other nanowire of the first plurality of nanowires. The first thermoelectric film may be selected from the group consisting of p-type thermoelectric film and n-type thermoelectric film. The first plurality of nanowires may comprise p-type nanowires and the first thermoelectric film may comprise p-type thermoelectric film. The first plurality of nanowires may comprise n-type nanowires and the first thermoelectric film may comprises n-type thermoelectric film. The composite may further comprise a second plurality of nanowires embedded within a second thermoelectric film. The first plurality of nanowires may comprise p-type nanowires and the first thermoelectric film may comprise p-type thermoelectric film. The second plurality of nanowires may comprise n-type nanowires and the second thermoelectric film may comprise n-type thermoelectric film.

Another embodiment is a thermoelectric nanowire composite array, comprising: a first electrical contact; a first bundle comprising a plurality of p-type nanowires that are about parallel to each other and are embedded within p-type thermoelectric film, wherein the first bundle comprises a first bundle end one and first bundle end two, wherein the first bundle end one and the first bundle end two are at opposite ends of the p-type nanowires, wherein the first bundle end one is electrically connected to the first electrical contact; a second electrical contact electrically connected to the first bundle end two; a second bundle comprising a plurality of n-type nanowires that are about parallel to each other and are embedded within n-type thermoelectric film, wherein the second bundle comprises a second bundle end one and second bundle end two, wherein the second bundle end one and the second bundle end two are at opposite ends of the n-type nanowires, wherein the second bundle end one is electrically connected to the second electrical contact; and a third electrical contact electrically connected to the second bundle end two. The plurality of p-type nanowires may be about parallel to the plurality of n-type nanowires. The array may further comprise a heat sink and a direct current (DC) source having a negative terminal and a positive terminal, wherein the first electrical contact and the third electrical contact may be thermally connected to the heat sink, wherein the first electrical contact may be electrically connected to the negative terminal of the DC source and wherein the third electrical contact may he electrically connected to the positive terminal of the DC current source. The array may further comprise an object to be cooled, wherein the second electrical contact may be thermally connected to an object to be cooled. The array may further comprise a heat sink and a resistor having a first terminal and a second terminal, wherein the first electrical contact and the third electrical contact may be thermally connected to the heat sink, wherein the first electrical contact may be electrically connected to the first terminal of the resistor and wherein the third electrical contact may be electrically connected to the second terminal of the resistor. The array may further comprise an object to be heated, wherein the second electrical contact is thermally connected to an object to be heated.

In another embodiment, a thermoelectric nanowire composite array comprises: a first, electrical contact; a first bundle comprising a plurality of n-type nanowires that are about parallel to each other and are embedded within n-type thermoelectric film, wherein the first bundle comprises a first bundle end one and first bundle end two, wherein the first bundle end one and the first bundle end two are at opposite ends of the plurality of n-type nanowires, wherein the first bundle end one is electrically connected to the first electrical contact; a second electrical contact electrically connected to the first bundle end two; a second bundle comprising a plurality of p-type nanowires that are about parallel to each other and are embedded within p-type thermoelectric film, wherein the second bundle comprises a second bundle end one and second bundle end two, wherein the second bundle end one and the second bundle end two are at opposite ends of the plurality of p-type nanowires, wherein the second bundle end one is electrically connected to the second electrical contact; and a third electrical contact electrically connected to the second bundle end two. The plurality of p-type nanowires may be about parallel to the plurality of n-type nanowires.

Other embodiments will be apparent to those skilled in the art based on the disclosure herein.

### BRIEF DESCRIPTION OF THE DRAWINGS

The accompanying drawings, which are incorporated into and form a part of the disclosure, illustrate embodiments of the invention and, together with the description, serve to explain the principles of the invention.

FIG. 1A shows a side diagram of a three plenum showerhead used in embodiments of the present MOCVD process.

FIG. 1B shows a bottom view of the three plenum showerhead of FIG. 1A.

FIG. 2 shows a thin silicon nitride layer is deposited on a GaSb substrate by a plasma enhanced chemical vapor deposition method.

FIG. 3 illustrates metal e-beam evaporation of Au onto photolithographically produced pads.

FIG. 4 shows the formation of a uniform conformal silicon dioxide layer.

FIG. 5 shows photoresist coated on top of the silicon dioxide layer.

FIG. 6 shows the use of photolithography to pattern the p-mask on the resist.

FIG. 7 illustrates deep reactive ion etching (DRIE) to etch the p-holes in the silicon dioxide layer.

FIG. 8 shows the photoresist stripped by acetone leaving the p-holes in the silicon dioxide layer.

FIG. 9 shows p-type thermoelectric nanowires grown in the p-holes of FIG. 8.

FIG. 10 shows a p-type thermoelectric film filled into the p-holes to embed the p-type nanowires.

FIG. 11 shows the p-types nanowires embedded in film.

FIG. 12 shows photoresist coated on top of the p-leg filled silicon dioxide layer.

FIG. 13 illustrates the use of photolithography to pattern the corresponding n-mask on the resist.

FIG. 14 illustrates the use of DRIE to etch the n-holes in the silicon dioxide layer.

FIG. 15 shows the photoresist shipped by acetone, leaving the n-holes.

FIG. 16 shows n-type thermoelectric nanowires grown in the n-holes of FIG. 15.

FIG. 17 shows n-type thermoelectric films filled into the n-holes to embed the n-type nanowires.

FIG. 18 shows p-type nanowires embedded in p-type film, n-type nanowires embedded in n-type film and the silicon dioxide layer.

FIG. 19 shows metal e-beam evaporation used to deposit Au in those top contact pads.

FIG. 20 shows an oblique view of a thermoelectric cooler fabricated with a thermoelectric nanowire composite device according to the present invention.

FIG. 21 shows an oblique view of a thermoelectric power generator fabricated with a thermoelectric nanowire composite device according to the present invention.

### DETAILED DESCRIPTION OF THE INVENTION

Embodiments of the present invention include an MOCVD deposition process to synthesize and dope nanowires as well as to form their composite films. The deposition steps of this process are compatible with traditional microfabrication process steps. The metal organic chemicals used as precursors for the MOCVD process to form p- and n-type nanowire arrays and p- and n-type thermoelectric films can chosen to be less toxic and much safer than conventional triethyl- and trimethyl-precursors.

The MOCVD process provides aligned p- and n-type nanowire arrays which are then filled with p- and n-type thermoelectric films to form the respective p-leg and n-leg of a thermoelectric device. The thermoelectric nanowire synthesis process is integrated with a photolithographic microfabrication process. The locations of the p- and n-type nanowire micro arrays are defined by photolithography. Metal contact pads at the bottom and top of these nanowire arrays which link the p- and n-type nanowires in series are defined and aligned by photolithography.

Flash (or partial) evaporation is the partial vaporization that occurs when a saturated liquid stream undergoes a reduction in pressure by passing through a throttling valve or other throttling device. Quick flash evaporation is used in the MOCVD precursor delivery process. Metal organics are dissolved in octane solvents, and delivered in liquid form through liquid pumps which can control solvent flow in microliter per min scale and vaporize the precursors in a quick flash evaporator to introduce the metal organic precursors to the reaction chamber. Quick flash evaporators permit minimum MO chemical usage (safe) and quick gas switch (capable of super lattice and quantum dots growth).

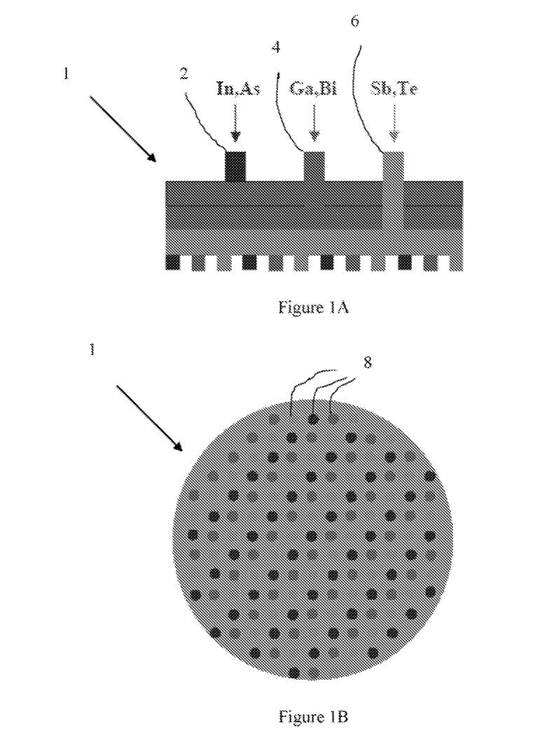

A three-plenum showerhead is used in the MOCVD reaction chamber. This showerhead permits separate delivery of three MO materials to the gap between the substrate and the showerhead with no pre-mixing of gases. A custom-designed jet configuration insures uniform gas delivery. More than 250 jets are provided on the showerhead. FIG. 1A shows a side diagram of a three plenum showerhead used in some embodiments of the present MOCVD process. The figure illustrates a showerhead 1 with exemplary material inputs 2, 4, and 6. FIG. 1B shows a bottom view of the three plenum showerhead 1 of FIG. 1A. The array of dots 8 are representative of a controlled distribution of material In, As, Ga, Bi, and Sb, Te from inputs 2, 4 and 6 respectively. The metal organic chemicals used as precursors to form p- and n-type nanowire arrays and films can be chosen to be less toxic and much safer than conventional Methyl- and trimethyl-precursors. Exemplary metal organic precursors usable in the present invention are as follows: for In: 5 wt % Pentamethylcyclopentadienylindium (CH₃)₅C₅In in octane; for As: 5 wt % Triphenylarsine (C₆H₅)₃As in octane; for Ga: 5 wt % Tris(2,2,6,6-tetramethyl-3,5-heptanedionato)gallium Ga(TMHD)₃ in octane; for Bi: 5 wt % Triphenylbismuth (C₆H₅)₃Bi in octane; for Sb: 5 wt % Triphenylantimony (C₆H₅)₃Sb in octane; and for Te: 5 wt % Tellurium ethoxide in octane.

P-type nanowires and films from different combinations of metal organic precursors are shown in Table 1 below.

TABLE 1

| In | As | Ga | Bi | Sb | Te |
|---|---|---|---|---|---|
| X | | X | | X | |
| X | | | X | X | |
| | | | X | X | X |

N-type nanowires and films from different combinations of metal organic precursors are shown in Table 2 below.

TABLE 2

| In | As | Ga | Bi | Sb | Te |
|---|---|---|---|---|---|
| X | | | | X | X |
| X | X | | | X | |
| | | | X | X | X |

In a general embodiment for fabricating thermoelectric nanowire composite arrays, an insulating layer such as silicon nitride is deposited onto a substrate. Bottom electrical contacts are formed on the insulating layer. Silicon dioxide layer is then deposited through a TEOS (Tetraethyl orthosilicate) CVD process onto the bottom electrical contacts. A photoresist layer is spin-coated onto the silicon dioxide layer. Portions of the photoresist and silicon dioxide layer are etched away, exposing portions of the bottom electrical contacts. Next, the photoresist is stripped. P- or n-type nanowires are deposited in the etched holes. In this general embodiment, the p-type nanowires are deposited first, so the holes in this embodiment are referred to as the p-holes. The n-typed nanowires will be deposited in a later step, although reversing the order is within the scope of this invention. A p-type film is then deposited in the p-holes. Excess p-type film is then polished away such that the p-type film fills and is flush with the top of the p-holes. Another coating of photoresist is deposited over the remaining silicon dioxide layer and the tops of the p-holes. A n-mask is patterned on the resist. The n-holes are etched in the openings of the n-mask down to the electrically conducting layer. After etching, the photoresist is stripped. N-type thermoelectric nanowires are then grown in these holes. N-type thermoelectric films are then filled up in these holes to embed the n-type nanowires. The n-type thermoelectric film that is not in the defined n-holes is then polished away. The corresponding top metal contact pads are formed. This produces a thermoelectric nanowire composite that can then be configured in a thermoelectric device.

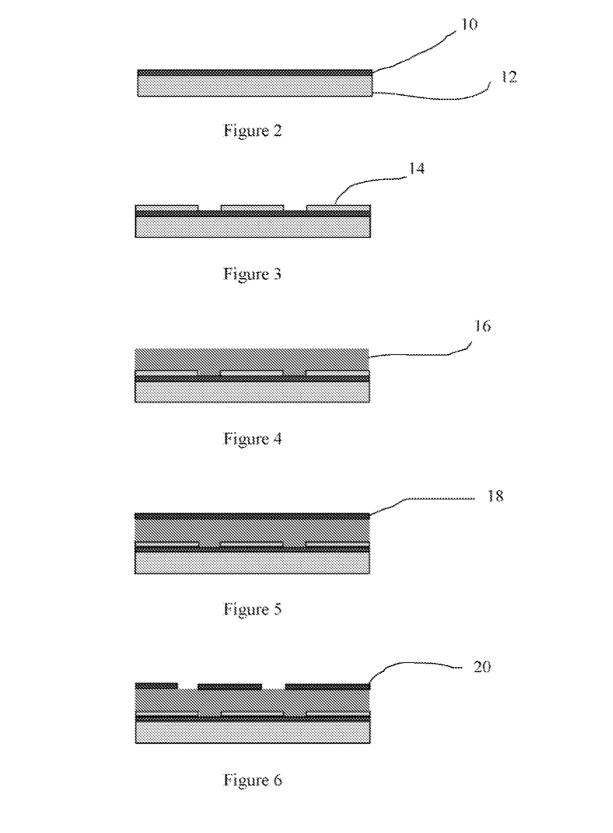

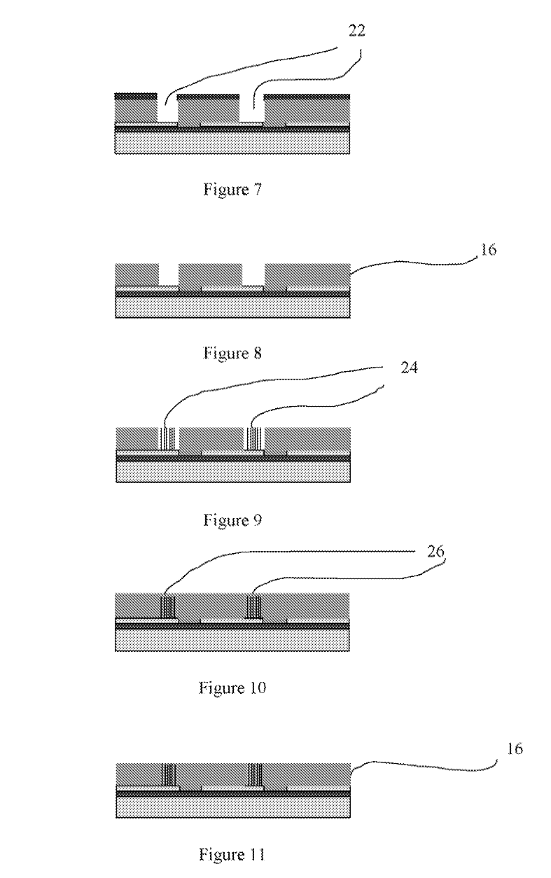

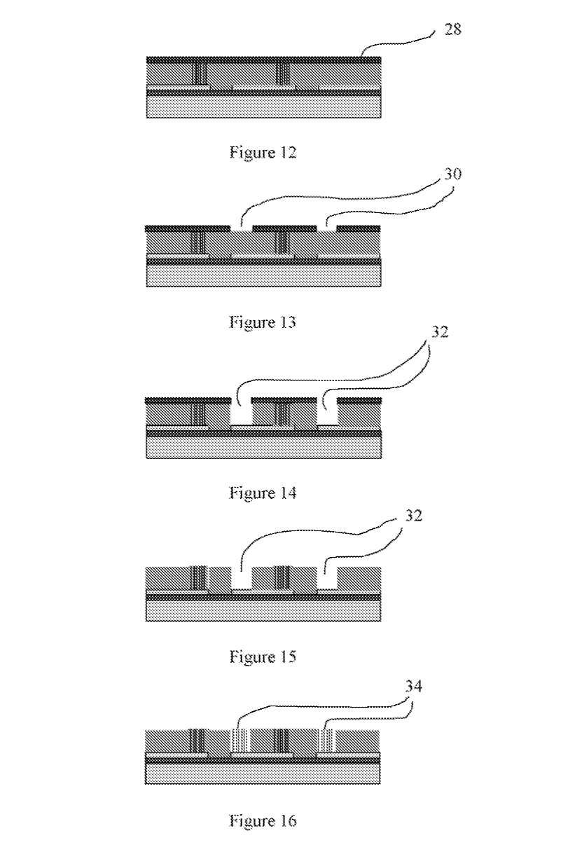

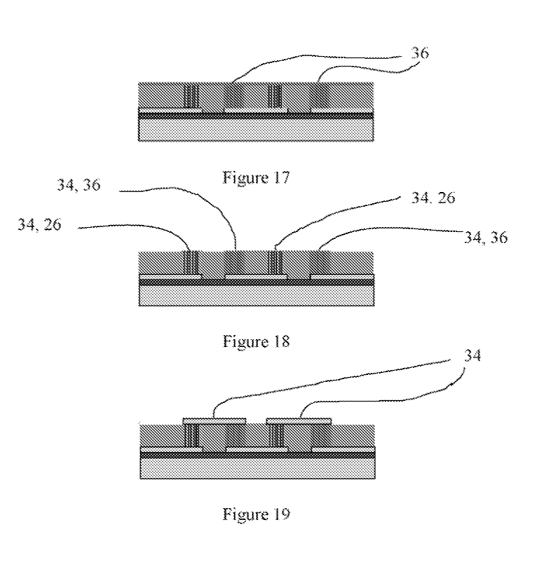

FIGS. 2-19 illustrate the steps of an exemplary process for fabricating thermoelectric nanowire composite arrays by MOCVD. A thin silicon nitride layer 10 is deposited on a GaSb substrate 12 by a plasma enhanced chemical vapor deposition method (FIG. 2). Photolithography is used to pattern the bottom contact pads on the silicon nitride layer. Metal e-beam evaporation is used to deposit Au 14 on those pads (FIG. 3). Silicon dioxide is then deposited through a TEOS CVD process on the Au patterned substrate and exposed portions of the thin silicon nitride layer. A uniform conformal silicon dioxide layer is formed 16 (FIG. 4). Photoresist 18 is coated on top of the silicon dioxide layer (FIG. 5). Photolithography is used to pattern the p-mask 20 on the resist (FIG. 6). Deep reactive ion etching (DRIE) is used to etch the p-holes 22 in the silicon dioxide layer FIG. 7. After etching, the photoresist is stripped by acetone leaving the p-holes 22 in the silicon dioxide layer 16 (FIG. 8). P-type thermoelectric nanowires 24 are then grown in these holes using the MOCVD method (FIG. 9). A p-type thermoelectric film 26 is then filled into these holes to embed the p-type nanowires using the MOCVD method (FIG. 10). The p-type composite leg is thus formed. A chemical mechanical polishing (CMP) method is then used to polish away the p-type thermoelectric films that are not in the defined p-holes but on top of the silicon dioxide layer, leaving only the exposed silicon dioxide layer 16 and the p-types nanowires 24 embedded in film 26 (FIG. 11). Photoresist 28 is coated on top of the p-leg filled silicon dioxide layer (FIG. 12). Photolithography is used to pattern the corresponding n-mask 30 on the resist (FIG. 13). DRIE is used to etch the n-holes 32 in the silicon dioxide layer (FIG. 14). After etching, the photoresist is stripped by acetone, leaving the n-holes 32 (FIG. 15). N-type thermoelectric nanowires 34 are then grown in these holes using MOCVD method (FIG. 16). N-type thermoelectric films 36 are then filled into these holes to embed the n-type nanowires using MOCVD method (FIG. 17). The n-type composite leg is thus formed. The CMP method is used to polish away the n-type thermoelectric films that are not in the defined n-holes but on top of the silicon dioxide layer, leaving exposed the p-type nanowires 24 embedded in p-type film 26, the n-type nanowires 34 embedded in n-type film 36 and the silicon dioxide layer 16 (FIG. 18). Photoresist is coated on top of the p-leg and n-leg filled silicon dioxide layer. Photolithography is used to align and pattern the corresponding fop metal contact pads on the resist. Metal e-beam evaporation is used to deposit Au 38 in those top contact pads (FIG. 19). The photoresist is stripped by acetone. The thin silicon nitride layer 10 and GaSb substrate 12 can be removed for some applications. The thermoelectric nanowire composite device can be used in either a thermoelectric heater or cooler.

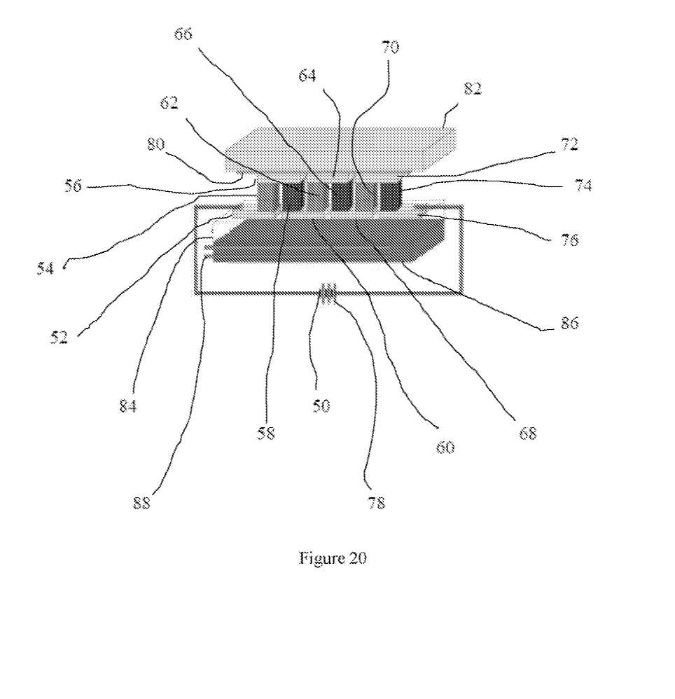

FIG. 20 shows an oblique view of a thermoelectric cooler fabricated with a thermoelectric nanowire composite device according to the present invention. The thermoelectric nanowire composite device includes hot-side metal contacts (52, 60, 68, 76) and cold-side metal contacts (56, 64, 72). The device includes p-type nanowire composites (54, 62, 70) and n-type nanowire composites (58, 66, 74) configured, as discussed below, to be connected electrically in series and thermally in parallel. The serial electrical connection can be viewed as following a path from the negative terminal 50 of a DC power source through metal contact 52, p-type nanowire composite 54, metal contact 56, n-type nanowire composite 58, metal contact 60, p-type nanowire composite 62, metal contact 64, n-type nanowire composite 66, metal contact 68, p-type nanowire composite 70, metal contact 72, n-type nanowire composite 74, metal contact 76 and to the positive terminal 78 of the DC power source. The cold-side metal contacts (56, 64, 72) are in contact with ceramic substrate 80, which is in contact with an object to be cooled 82. The hot-side metal contacts are (52, 60, 68, 76) in contact with a substrate 84 which is connected to a heat sink 86 which includes an internal coolant flow path 88 (water in this embodiment).

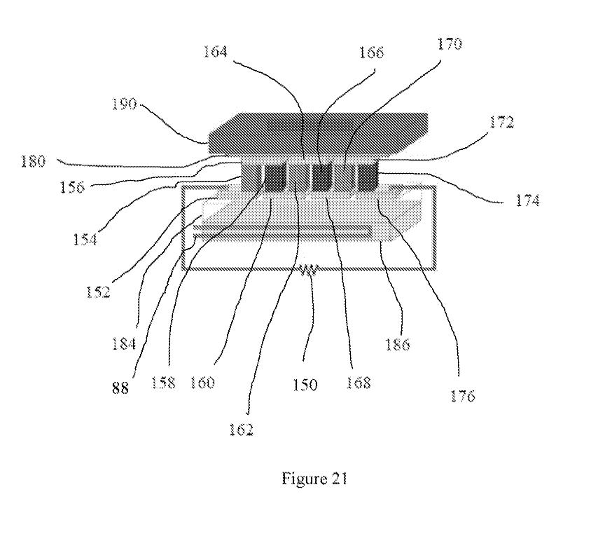

FIG. 21 shows an oblique view of a thermoelectric power generator fabricated with a thermoelectric nanowire composite device according to the present invention. The thermoelectric nanowire composite device includes cold-side metal contacts (152, 160, 168, 176) and hot-side metal contacts (156, 164, 172). The device includes p-type nanowire composites (154, 162, 170) and n-type nanowire composites (158, 166, 174) configured, as discussed below.

Due to the temperature gradient between the hot and cold sides, electrons in the n-type materials and holes in the p-type materials will flow from the hot side to the cold side (in the same direction), and therefore, will generate electrical current flow through the p-type and n-type nanowire composite arrays. This is essentially operated like a thermoelectric battery which can be used to power an electrical device (which is represented here as a resist). The electrical flow can be viewed as following a path from p-type nanowire composite 154, metal contact 156, n-type nanowire composite 158, metal contact 160, p-type nanowire composite 162, metal contact 164, n-type nanowire composite 166, metal contact 168, p-type nanowire composite 170, metal contact 172, n-type nanowire composite 174, metal contact 176 and then flow through the resist 150. Both the hot-side metal contacts (156, 164, 172) and the cold side metal contacts (152, 160, 168, 176) are in contact with different ceramic pieces (180 for cold side, 184 for hot side), which can be of different ceramic materials or the same material depending on the device operating temperatures. The cold-side (152, 160, 168, 176) is in contact with ceramic piece 184 which is connected to heat sink 186 which can be used to dump the heat it collected from the hot side 190.

The foregoing description of the invention has been presented for purposes of illustration and description and is not intended to be exhaustive or to limit the invention to the precise form disclosed. Many modifications and variations are possible in light of the above teaching. The embodiments disclosed were meant only to explain the principles of the invention and its practical application to thereby enable others skilled in the art to best use the invention in various embodiments and with various modifications suited to the particular use contemplated. The scope of the invention is to be defined by the following claims.

I claim:

1. A method for fabricating a thermoelectric nanowire composite array, comprising:
depositing an insulating layer on a substrate;
forming bottom electrical contacts on said insulating layer;
depositing a silicon dioxide layer onto said bottom electrical contacts;
producing a p-composite and an n-composite, wherein producing a p-composite comprises;
coating a first photoresist layer onto said silicon dioxide layer;
patterning first openings in said first photoresist layer to produce a mask selected from a group consisting of a p-mask and an n-mask;
etching in said first openings to etch away portions of said silicon dioxide layer to produce first holes that exposes first portions of said bottom electrical contacts;
stripping away said first photoresist layer;
depositing p-type nanowires in said first holes to produce p-holes;
depositing p-type film in said p-holes to embed said p-type nanowires in said p-type film to produce a p-composite in each said p-hole; and
polishing away excess p-type film, and
wherein producing an n-composite comprises:
coating a second photoresist layer on said silicon dioxide layer and over said p-holes;
patterning second openings in said second photoresist layer to produce an n-mask;
etching in said second openings to etch away portions of said silicon dioxide layer to produce second holes that exposes second portions of said bottom, electrical contacts;
stripping away said second photoresist layer;
depositing n-type nanowires in said second holes to produce n-holes;
depositing n-type film in said n-holes to embed said n-type nanowires in said n-type film to produce an n-composite in each said n-hole; and
polishing away excess n-type film; and
forming top metal contact pads to electrically connecting a p-composite to an n-composite.

2. The method of claim 1, wherein said insulating layer is deposited through a TEOS (Tetraethyl orthosilicate) CVD process.

3. The method of claim 2, wherein said insulating layer comprises silicon nitride.

4. The method of claim 1, wherein said first photoresist layer and said second photoresist layer are spin-coated onto said silicon dioxide layer.

5. The method of claim 1, wherein each of said p-type nanowires, said p-type film, said n-type nanowires and said n-type film are deposited by an MOCVD process.

6. The method of claim 5, wherein said MOCVD process uses a three-plenum showerhead in the MOCVD reaction chamber.

7. The method of claim 6, wherein said three-plenum showerhead permits separate delivery of three MO materials to the gap between said substrate and said showerhead with no pre-mixing of gases.

8. The method of claim 6, wherein said three-plenum showerhead comprises at least 250 jets.

9. The method of claim 5, wherein said MOCVD process uses metal organic precursors selected from the group consisting of Pentamethylcyclopentadienylindium (CH₃)₅C₅In in octane, Triphenylarsine (C₆H₅)₃As in octane, Tris(2,2,6,6-tetramethyl-3,5-heptanedionato)gallium Ga(TMHD)₃ in octane, Triphenylbismuth (C₆H₅)₃Bi in octane, Triphenylantimony (C₆H₅)₃Sb in octane and Tellurium ethoxide in octane.

10. The method of claim 1, wherein said p-type nanowires and films are produced from a combination of metal organic precursors selected from the group consisting of (i) In, Ga and Sb, (ii) In, Bi and Sb and (iii) Bi, Sb and Te.

11. The method of claim 10, wherein said In comprises about 5 wt % Pentamethylcyclopentadienylindium (CH₃)₅C₅In in octane, wherein said Ga comprises about 5 wt % Tris(2,2,6,6-tetramethyl-3,5-heptanedionato)gallium Ga(TMHD)₃ in octane, wherein said Bi comprises about 5 wt % Triphenylbismuth (C₆H₅)₃Bi in octane, wherein said Sb comprises about 5 wt % Triphenylantimony (C₆H₅)₃Sb in octane and wherein said Te comprises about 5 wt % Tellurium ethoxide in octane.

12. The method of claim 1, wherein said n-type nanowires and films are produced from a combination of metal organic precursors selected from the group consisting of (i) In, Sb and Te, (ii) In, As and Sb and (iii) Bi, Sb and Te.

13. The method of claim 12, wherein said In comprises about 5 wt % Pentamethylcyclopentadienylindium (CH₃)₅C₅In in octane, said As comprises about 5 wt % Triphenylarsine (C₆H₅)₃As in octane, said Ga comprises about 5 wt % Tris(2,2,6,6-tetramethyl-3,5-heptanedionato)gallium Ga(TMHD)₃ in octane, said Bi comprises about 5 wt % Triphenylbismuth (C₆H₅)₃Bi in octane, said Sb comprises about 5 wt % Triphenylantimony (C₆H₅)₃Sb in octane, and said Te comprises about 5 wt % Tellurium ethoxide in octane.

14. The method of claim 1, wherein at least one of (i) said p-type nanowires, (ii) said p-type film, (iii) said n-type nanowires and (iv) said n-type film are formed from precursors delivered to a MOCVD reaction chamber by quick flash evaporation.

15. A method for fabricating a thermoelectric nanowire composite array, comprising:
depositing an insulating layer on a substrate;
forming bottom electrical contacts on said insulating layer;
depositing a silicon dioxide layer onto said bottom electrical contacts;
coating a first photoresist layer onto said silicon dioxide layer;
patterning first openings in said first photoresist layer to produce a p-mask;
etching in said first openings to etch away portions of said silicon dioxide layer to produce first holes that exposes first portions of said bottom electrical contacts;
stripping away said first photoresist layer;
depositing p-type nanowires in said first holes to produce p-holes;
depositing p-type film in said p-holes to embed said p-type nanowires in said p-type film to produce a p-composite in each said p-hole;
polishing away excess p-type film;
coating a second photoresist layer on said silicon dioxide layer and over said p-holes;
patterning second openings in said second photoresist layer to produce an n-mask;
etching in said second openings to etch away portions of said silicon dioxide layer to produce second holes that exposes second portions of said bottom electrical contacts;
stripping away said second photoresist layer;
depositing n-type nanowires in said second holes to produce n-holes;
depositing n-type film in said n-holes to embed said n-type nanowires in said n-type film to produce an n-composite in each said n-hole;
polishing away excess n-type film; and
forming top metal contact pads to electrically connecting a p-composite to an n-composite.

16. A method for fabricating a thermoelectric nanowire composite array, comprising;
depositing an insulating layer on a substrate;
forming bottom electrical contacts on said insulating layer;
depositing a silicon dioxide layer onto said bottom electrical contacts;
coating a first photoresist layer onto said silicon dioxide layer;
patterning first openings in said first photoresist layer to produce a n-mask;
etching in said first openings to etch away portions of said silicon dioxide layer to produce first holes that exposes first portions of said bottom electrical contacts;
stripping away said first photoresist layer;
depositing n-type nanowires in said first holes to produce n-holes;
depositing n-type film in said n-holes to embed said n-type nanowires in said n-type film to produce an n-composite in each said n-hole;
polishing away excess n-type film;
coating a second photoresist layer on said silicon dioxide layer and over said n-holes;
patterning second openings in said second photoresist layer to produce an p-mask;
etching in said second openings to etch away portions of said silicon dioxide layer to produce second holes that exposes second portions of said bottom electrical contacts;
stripping away said second photoresist layer;
depositing p-type nanowires in said second holes to produce p-holes;
depositing p-type film in said p-holes to embed said p-type nanowires in said p-type film to produce a p-composite in each said p-hole;
polishing away excess p-type film; and
forming top metal contact pads to electrically connecting a p-composite to an n-composite.

17. A method, comprising:
MOCVD depositing p-type nanowires onto an electrical contact; and
MOCVD deposing p-type thermoelectric film onto said p-type nanowires to embed said p-type nanowires in said p-type thermoelectric film.

18. A method, comprising:
MOCVD depositing n-type nanowires onto an electrical contact; and
MOCVD deposing n-type thermoelectric film onto said n-type nanowires to embed said n-type nanowires in said n-type thermoelectric film.

19. A method, comprising:
MOCVD depositing p-type nanowires onto an electrical contact;
MOCVD deposing p-type thermoelectric film onto said p-type nanowires to embed said p-type nanowires in said p-type thermoelectric film;
MOCVD depositing n-type nanowires onto an electrical contact; and
MOCVD deposing n-type thermoelectric film onto said n-type nanowires to embed said n-type nanowires in said n-type thermoelectric film.

20. A thermoelectric nanowire composite, comprising a first plurality of p-type nanowires embedded in a first p-type thermoelectric film, wherein each nanowire of said first plurality of p-type nanowires is aligned to be about parallel with each other nanowire of said first plurality of p-type nanowires.

21. A thermoelectric nanowire composite, comprising a first plurality of nanowires embedded within a first thermoelectric film.

22. The composite of claim 21, wherein said first plurality of nanowires are selected from the group consisting of p-type nanowires and n-type nanowires.

23. The composite of claim 21, wherein said first plurality of nanowires are about parallel to each other nanowire of said first plurality of nanowires.

24. The composite of claim 21, wherein said, first thermoelectric film is selected from the group consisting of p-type thermoelectric film and n-type thermoelectric film.

25. The composite of claim 21, wherein said first plurality of nanowires comprise p-type nanowires and said first thermoelectric film comprises p-type thermoelectric film.

26. The composite of claim 21, wherein said first plurality of nanowires comprise n-type nanowires and said first thermoelectric film comprises n-type thermoelectric film.

27. The composite of claim 21, further comprising a second plurality of nanowires embedded within a second thermoelectric film.

28. The composite of claim 27, wherein said first plurality of nanowires comprise p-type nanowires and said first thermoelectric film comprises p-type thermoelectric film and wherein said second plurality of nanowires comprise n-type nanowires and said second thermoelectric film comprises n-type thermoelectric film.

29. A thermoelectric nanowire composite array, comprising:
a first electrical contact;
a first bundle comprising a plurality of p-type nanowires that are about parallel to each other and are embedded within p-type thermoelectric film, wherein said first bundle comprises a first bundle end one and first bundle end two, wherein said first bundle end one and said first bundle end two are at opposite ends of said p-type nanowires, wherein said first bundle end one is electrically connected to said first electrical contact;
a second electrical contact electrically connected to said first bundle end two;
a second bundle comprising a plurality of n-type nanowires that are about parallel to each other and are embedded within n-type thermoelectric film, wherein said second bundle comprises a second bundle end one and second bundle end two, wherein said second bundle end one and said second bundle end two are at opposite ends of said n-type nanowires, wherein said second bundle end one is electrically connected to said second electrical contact; and
a third electrical contact electrically connected to said second bundle end two.

30. The array of claim 29, wherein a said plurality of p-type nanowires are about parallel to said plurality of n-type nanowires.

31. The array of claim 29, further comprising a heat sink and a direct current (DC) source having a negative terminal and a positive terminal, wherein said first electrical contact and said third electrical contact are thermally connected to said heat sink, wherein said first electrical contact is electrically connected to said negative terminal of said DC source and wherein said third electrical contact is electrically connected to said positive terminal of said DC current source.

32. The array of claim 31, further comprising an object to be cooled, wherein said second electrical contact is thermally connected to an object to be cooled.

33. The array of claim 29, further comprising a heat sink and a load having a first terminal and a second terminal, wherein said first electrical contact and said third electrical contact are thermally connected to said heat sink, wherein said first electrical contact is electrically connected to said first terminal of said load and wherein said third electrical contact is electrically connected to said second terminal of said load.

34. A thermoelectric nanowire composite array, comprising:
a first electrical contact;
a first bundle comprising a plurality of n-type nanowires that are about parallel to each other and are embedded within n-type thermoelectric film, wherein said first bundle comprises a first bundle end one and first bundle end two, wherein said first bundle end one and said first bundle end two are at opposite ends of said plurality of n-type nanowires, wherein said first bundle end one is electrically connected to said first electrical contact;
a second electrical contact electrically connected to said first bundle end two;
a second bundle comprising a plurality of p-type nanowires that are about parallel to each other and are embedded within p-type thermoelectric film, wherein said second bundle comprises a second bundle end one and second bundle end two, wherein said second bundle end one and said second bundle end two are at opposite ends of said plurality of p-type nanowires, wherein said second bundle end one is electrically connected to said second electrical contact; and
a third electrical contact electrically connected to said second bundle end two.

35. The array of claim 35, wherein a said plurality of p-type nanowires are about parallel to said plurality of n-type nanowires.
